(19) United States
(12) Patent Application Publication
(10) Pub. No.: US 2008/0150061 A1
(43) Pub. Date: Jun. 26, 2008

(54) Producing optical microlenses on a semiconductor device

(75) Inventors: Yannick Sanchez, Saint Nazaire Les Eymes (FR); Nicolas Hotellier, Grenoble (FR); Alain Inard, Saint Nazaire Les Eymes (FR)

Correspondence Address: DOCKET CLERK, P.O. DRAWER 800889, DALLAS, TX, 75380, US

(73) Assignee: STMICROELECTRONICS SA, Montrouge (FR)

(21) Appl. No.: 11/999,781

(22) Filed: Dec. 7, 2007

(30) Foreign Application Priority Data
Dec. 21, 2006 (FR) 06/55813

(51) Int. Cl. H01L 31/0232; H01L 31/18; C23C 16/513

(52) U.S. Cl. 257/432; 438/69; 118/723 R; 257/E31.127

(57) ABSTRACT

A system and method for producing optical microlenses on a front layer of a semiconductor device. The system and method includes depositing a final layer of a suitable material on a front layer of a semiconductor device. The system and method could also include producing crossed grooves in the final layer down to the front layer forming spaced-apart pads and then treating the pads so that the pads exhibit a substantially domed shape. In addition, an apparatus to produce optical microlenses could include a chamber to accommodate the semiconductor device and a heating element to heat the chamber. The apparatus could also include an ultraviolet radiation emitter associated with the chamber. The apparatus could further include a plasma generator configured to act on the front layer. Finally, a semiconductor device with optical microlenses which includes some sort of anti-fusion means between the microlenses is also provided.

### CROSS-REFERENCE TO RELATED APPLICATIONS

The present application is related to French Patent Application No. 06/55813, filed Dec. 21, 2006, entitled “PROCESS AND APPARATUS FOR PRODUCING OPTICAL MICROLENSES ON A SEMICONDUCTOR DEVICE”. French Patent Application No. 06/55813 is assigned to the assignee of the present application and is hereby incorporated by reference into the present disclosure as if fully set forth herein. The present application hereby claims priority under 35 U.S.C. §119(a) to French Patent Application No. 06/55813.

### Technical Field

The present disclosure generally relates to optical semiconductor devices and more particularly to optical detectors.

### BACKGROUND

Conventional optical detectors or chips typically detect the light radiation passing through the optical microlenses. Such optical detectors generally include a multiplicity of pads constituting optical microlenses produced on a front layer and are configured to detect the light radiation passing through the optical microlenses. Such detectors are usually referred to as CMOS image sensors.

Conventional microlenses are typically made by depositing a final layer made of a suitable material to form the microlenses onto a front layer of a wafer. Crossed grooves are produced in the final layer down to the front layer, so as to form spaced apart parallelepipedal pads. These pads are then exposed, at room temperature, to illumination with ultraviolet radiation. The wafer is then placed in an oven preheated to a given temperature, generally between 150° C. and 250° C., so as to cause the pads to creep, giving them a domed shape, which are then crosslinked causing them to cure.

Unfortunately, when it is desired to improve the performance of such devices (i.e., to reduce the space between the optical microlenses, for example) to reduce their critical size or to increase their thickness, the risk of bridging (i.e., links by fusion, like adjacent water drops coming into contact with one another) between adjacent optical microlenses is increased during the creep. Accordingly, the microlenses do not have the desired shape. In general, for a microlens having sides of about 3 microns, the fusion between two neighbouring microlenses can typically be avoided only if the space separating them is greater than about 0.5 microns.

There is therefore a need for improved systems and methods for producing optical microlenses on a semiconductor device.

### SUMMARY

The present disclosure generally provides systems and methods for producing optical microlenses on a semiconductor device.

In one embodiment, the present disclosure provides a method of producing optical microlenses on a front layer of a semiconductor device. The method includes depositing a final layer of a suitable material on said front layer of said semiconductor device. The method could also include producing crossed grooves in said final layer down to said front layer forming spaced-apart pads. The method could further include treating said pads. The pads preferable exhibit a substantially domed shape.

In another embodiment, the present disclosure provides an apparatus to produce optical microlenses. The pads exhibit a substantially domed shape on a front layer of a semiconductor device. The apparatus could include a chamber to accommodate said semiconductor device and a heating element to heat said chamber. The apparatus could also include an ultraviolet radiation emitter associated with said chamber. The apparatus could further include a plasma generator configured to act on said front layer.

In still another embodiment, the present disclosure could include a semiconductor device. The semiconductor device could include a plurality of pads forming optical microlenses on a front layer of said semiconductor device. The front layer could include anti-fusion properties to prevent the adjacent edges of said pads from fusing together.

Other technical features may be readily apparent to one skilled in the art from the following figures, descriptions and claims.

### BRIEF DESCRIPTION OF THE DRAWINGS

For a more complete understanding of this disclosure and its features, reference is now made to the following description, taken in conjunction with the accompanying drawings, in which:

FIG. 1 shows a cross section of one embodiment of a device according to the present disclosure;

FIG. 2 shows a cross section of one embodiment of a device according to the present disclosure;

FIG. 2a shows a cross section of one embodiment of a device according to the present disclosure;

FIGS. 3 to 5 show top views of the aforementioned device according to one embodiment of the present disclosure;

FIG. 6 shows a cross section of the aforementioned device, during fabrication according to one embodiment of the present disclosure; and

FIG. 7 shows a cross section of an enclosure for the treatment of the aforementioned device according to one embodiment of the present disclosure.

### DETAILED DESCRIPTION

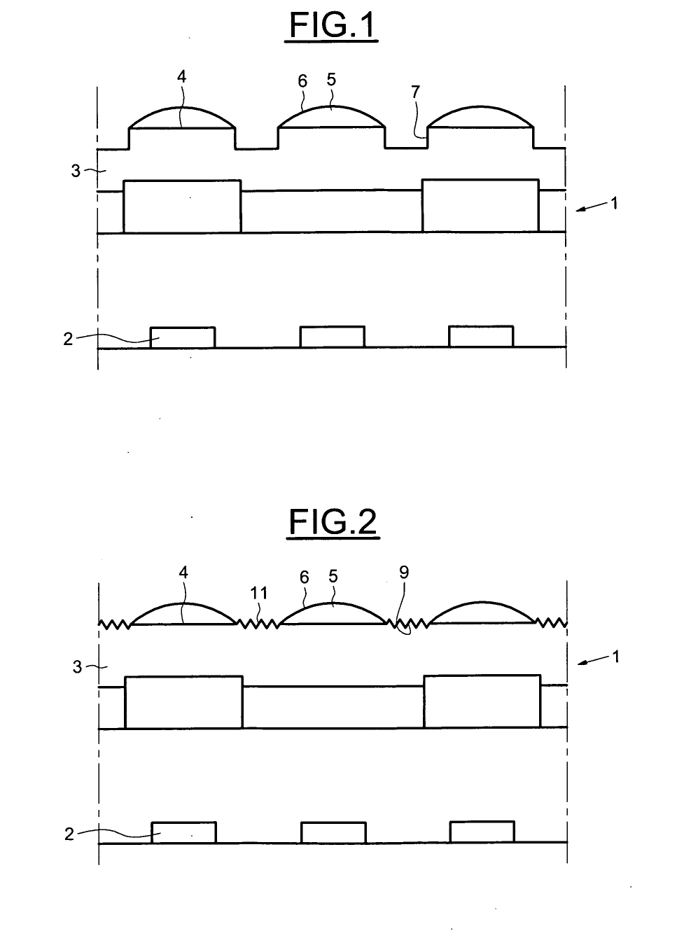

FIG. 1 shows a cross section of one embodiment of semiconductor device 1 according to the present disclosure. The embodiment of semiconductor device 1 shown in FIG. 1 is for illustration only. Other embodiments of semiconductor device 1 may be used without departing from the scope of this disclosure.

Semiconductor device 1 generally includes, in the depth, a multiplicity of optical detectors 2 having a plurality of CMOS circuits spaced apart and distributed, for example, in a square matrix.

Semiconductor device 1 could also include, to the front, a penultimate layer or planarization front layer 3 on the front face 4 of which a multiplicity of optical microlenses 5 is formed, said microlenses having domed front faces 6 and being spaced apart and distributed in a matrix, for example a square matrix, corresponding to the matrix of the detectors 2, in such a way that the external radiation is selectively directed via the optical microlenses 5 onto the detectors 2, optionally through suitable optical filters.

In the embodiment shown in FIG. 1, the optical microlenses 5 are separated by intersecting longitudinal and transverse notches 7 that are produced in the front layer 3.

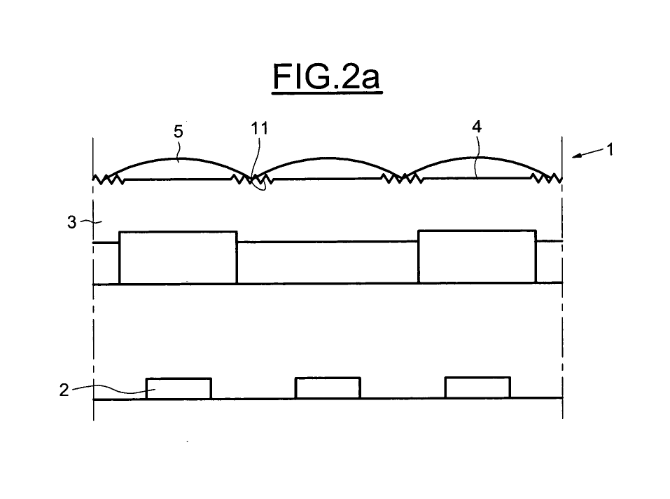

FIG. 2 shows a cross section of one embodiment of semiconductor device 1 according to the present disclosure. The embodiment of semiconductor device 1 shown in FIG. 2 is for illustration only. Other embodiments of semiconductor device 1 may be used without departing from the scope of this disclosure.

In the embodiment shown in FIG. 2, the optical microlenses 5 are separated by intersecting longitudinal and transverse zones 9 on the front surface 4 of the front layer 3. A surface treatment 11 is applied to these zones.

FIG. 2a shows a cross section of one embodiment of a semiconductor device 1 according to the present disclosure. The embodiment of semiconductor device 1 shown in FIG. 2a is for illustration only. Other embodiments of semiconductor device 1 may be used without departing from the scope of this disclosure. In the embodiment shown in FIG. 2a, the optical microlenses 5 have adjacent edges, in the zones in which the front layer 3 has a surface treatment 11.

The semiconductor device 1 may be fabricated in the following manner, by generally implementing the usual processes used in microelectronics, with which it is common practice to fabricate a large quantity of such devices on a common wafer 1a, which is generally shown by FIG. 7. The embodiment of shown in FIG. 7 is for illustration only. Other embodiments of may be used without departing from the scope of this disclosure.

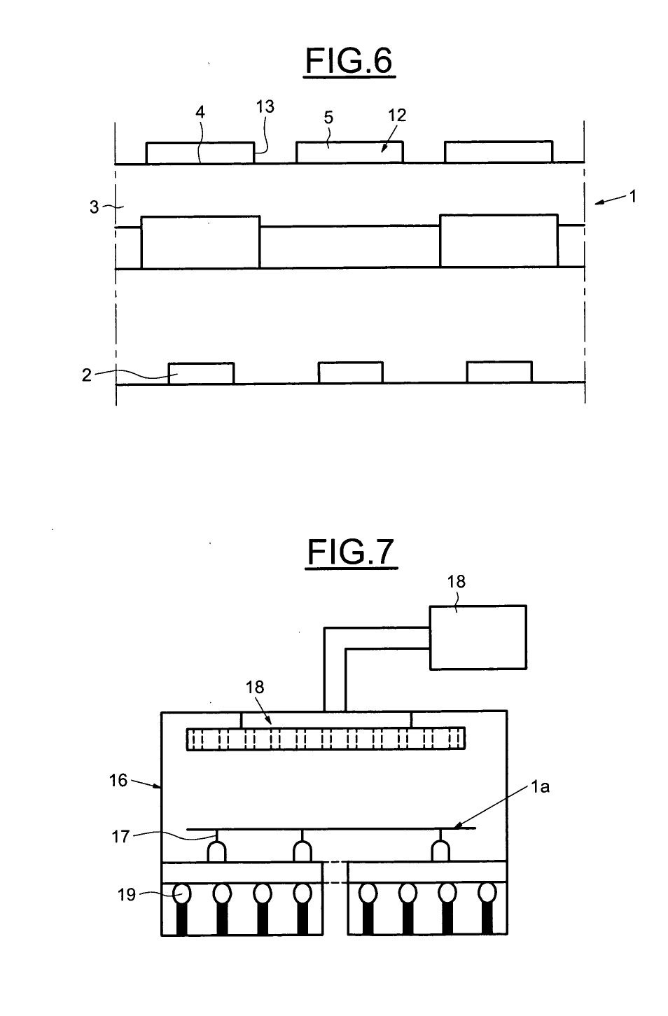

FIG. 6 shows a cross section of the semiconductor device 1 during fabrication according to one embodiment of the present disclosure. The embodiment of semiconductor device 1 shown in FIG. 6 is for illustration only. Other embodiments of semiconductor device 1 may be used without departing from the scope of this disclosure.

As shown in FIG. 6, once the device 1 has been fabricated as far as the planarization front layer 3, a final layer 12, for example made of an uncrosslinked transparent resin, is deposited on the front face 4 of this planarization layer. The thickness of this final layer may, for example, be between one tenth of a micron and one micron. The resin used may, for example, be crosslinked and cure under the effect of ultraviolet radiation and when its temperature is raised to at least 120° C.

Longitudinal grooves and transverse grooves 13 are then produced through the final layer 12 down to the front layer 3, so as to form a matrix of pads 15 corresponding to the locations of the optical microlenses 5 to be produced. The sides of the pads 15 may for example have a length of between 1 and 5 microns and the width of the grooves 13, that is to say the gap between the pads 15, may be between 0.05 and 0.5 microns.

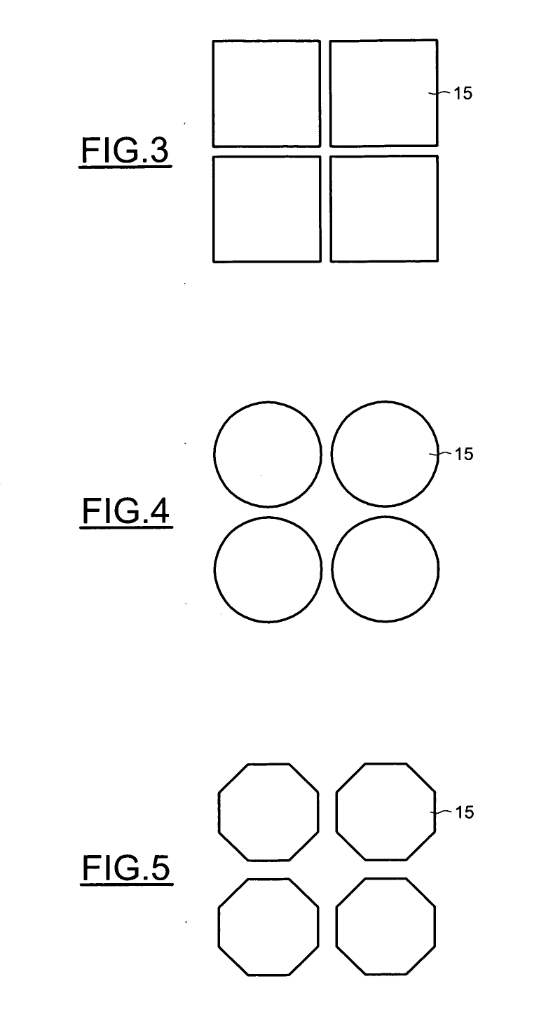

The pads 15 may have square outlines as shown in FIG. 3, round outlines as shown in FIG. 4 or polygonal outlines, preferably in the form of regular polygons, as shown in FIG. 5. Although FIGS. 3 to 5 show top views of semiconductor device 1 according to one embodiment of the present disclosure, it should be understood that the pads 15 shown in FIGS. 3 to 5 are for illustration only. Other embodiments of semiconductor device 1 may be used without departing from the scope of this disclosure.

Next, the wafer 1a is placed in the chamber of a known treatment enclosure 16 that contains a support 17 for accommodating said wafer, a plasma generator 18 and a series of halogen lamps 19 generally placed below the wafer and emitting radiation over a broad band, from ultraviolet to infrared, towards said wafer.

In general, with the enclosure 16 at a low temperature, for example at room temperature, that is to say at a temperature between 20° C. and 30° C., the halogen lamps 19 are switched on in a cycle and with a power such that, during a first phase, the temperature of the wafer 1a increases, approximately uniformly, up to a temperature range lying between about 120° C. and 250° C. and, in a second phase, the temperature reached is maintained. The temperature of the wafer 1a may be controlled by means of a thermocouple. The duration of the first phase may be between 1 land 30 seconds and the duration of the second phase may be between 1 and 60 seconds.

For example, the halogen lamps 19 are regulated in terms of power and operated in an on/off manner according to a program suitable for the temperature in the chamber of the enclosure 16 to be raised and maintained in the desired manner, and for the ultraviolet radiation to act on the pads 15.

In addition, the plasma generator 18 is switched on in at least one phase lying between said first phase and/or during said first phase and/or before said first phase and at the start of this first phase and/or astride the transition between said first phase and said second phase.

During the treatment procedure described above, on the one hand the resin of which the pads 15 are composed softens and momentarily becomes, below about 120° C., pasty or liquid, and creeps so as to adopt a domed shape and, on the other hand, the radiation of the lamps and the increase in temperature above 120° C. help to crosslink said resin and therefore to cure it.

At the same time, the plasma generator 18 is controlled, powerwise and timewise, so as to produce the following treatment. In other words, the controls of plasma generator 18 could be manipulated to change the RF power or the time of treatment permitted during any portion of the treatment.

If it is desired to produce the notches 7 as provided in the embodiment shown in FIG. 1, the plasma generator 18 is designed to produce a plasma that etches into the depth of the front layer 3, between the pads 15.

If it is desired to modify the surface state of the front layer 3 between the pads 15, for example to modify the hydrophilicity/hydrophobicity of this front layer 11, the plasma generator 18 is designed to produce a plasma for surface etching the front layer 3 between the pads 15, before or during their creep.

In both cases, the notches 7 or the modification in the surface state 11 constitute barriers or anti-fusion means that prevent the formation of bridges between the pads.

Known methods could be used to choose a suitable plasma according to the constituent material of the front layer 3. For example, if the front layer is made of an organic resin, the plasma may be an N₂H₂ with CF₄, with oxygen for producing the notches 7 and 8, or with or without oxygen for producing the surface treatment 11.

Accordingly, in one embodiment, the present disclosure provides optical microlenses 5, each having a perfectly formed domed surface 6. The peripheral edge of each of optical microlenses 5 is perfectly defined and formed. The adjacent peripheral edges of adjacent lenses are spaced apart or in contact, but without being fused together.

The present disclosure is not limited to the examples described above. Other embodiments are possible without departing from the scope defined by the appended claims. For example, a first subject of the present disclosure is a process for producing optical microlenses on a front layer of a semiconductor device, consisting: in depositing a final layer of a suitable material; in producing crossed grooves in said final layer down to said front layer, so as to constitute spaced-apart pads; and in carrying out a treatment so as to soften said pads, causing the latter to creep so as to give them a domed shape, and so as to cure them.

According to one embodiment, the present disclosure provides a system and method of treatment that includes placing the semiconductor device in the chamber of an enclosure at a low temperature. The system and method could also include heating the chamber so that the temperature in the chamber rises from a low temperature. In addition, the system and method could include generating ultraviolet radiation directed onto the pads and generating a plasma in the chamber so that the plasma acts on said front layer. Finally, the system and method include regulating the treatment both in terms of power-wise and time-wise with respect to one another, ensuring that, during the creep and the curing, adjacent edges of the pads do not fuse together.

In one embodiment, the plasma creates notches in the front layer, between the pads. According to another embodiment, the plasma modifies the surface state of the front layer, between said pads. In still other embodiments, the treatment consists in increasing the hydrophilicity/hydrophobicity of the front layer and/or of the pads.

According to one embodiment, the present disclosure provides a treatment that advantageously includes operating lamps emitting radiation over a broad band, from ultraviolet to infrared, as a heating means and/or emission means.

Another subject of the present disclosure is an apparatus intended for carrying out a treatment of pads formed on a front layer of a semiconductor device so that these pads become domed in order to form optical lenses.

According to the one embodiment, the present disclosure provides an apparatus having an enclosure (or chamber) for accommodating the semiconductor device, a means for heating the chamber, a means for emitting ultraviolet radiation, and a means for generating a plasma that acts on the front layer. In one embodiment, the present disclosure provides an apparatus that preferably includes lamps emitting radiation over a broad band, from ultraviolet to infrared, constituting the heating means and said emission means.

In one embodiment, the semiconductor device includes a multiplicity of pads that have to form, or forming, optical microlenses produced on a front layer. The front layer could include an anti-fusion means for preventing the adjacent edges of the pads from fusing together during production of the optical microlenses.

In one embodiment, the anti-fusion means includes notches produced in said front layer between said optical microlenses. In one embodiment, the anti-fusion means could include corrugations formed on the front layer, between the pads.

It may be advantageous to set forth definitions of certain words and phrases used in this patent document. The term “couple” and its derivatives refer to any direct or indirect communication between two or more elements, whether or not those elements are in physical contact with one another. The terms “include” and “comprise,” as well as derivatives thereof, mean inclusion without limitation. The term “or” is inclusive, meaning and/or. The phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A method of producing optical microlenses on a front layer of a semiconductor device, the method comprising:
depositing a final layer of a suitable material on said front layer of said semiconductor device;
producing crossed grooves in said final layer down to said front layer forming spaced-apart pads; and
treating said pads, wherein said pads exhibit a substantially domed shape.

2. The method according to claim 1 further comprising:
placing said semiconductor device in a chamber at a low temperature; and
heating said chamber.

3. The method according to claim 1 further comprising:
disposing ultraviolet radiation on said pads.

4. The method according to claim 1 further comprising:
generating plasma in said chamber, said plasma acting on said front layer to creates at least one of: a notch in said front layer between said pads, and a modified surface state of said front layer between said pads.

5. The method according to claim 1, wherein said treating comprises curing said pads.

6. The method according to claim 1 further comprising:
adjusting said treating so that adjacent edges of said pads do not fuse together.

7. The method according to claim 6, wherein said adjusting comprises adjusting at least one of: the curing time and the power intensity of said curing.

8. The method according to claim 1 further comprising:
increasing at least one of: a hydrophilicity and a hydrophobicity of said front layer.

9. The method according to claim 1 further comprising:
increasing at least one of: a hydrophilicity and a hydrophobicity of at least one of said pads.

10. An apparatus to produce optical microlenses wherein said pads exhibit a substantially domed shape on a front layer of a semiconductor device, the apparatus comprising:
a chamber to accommodate said semiconductor device;
a heating element to heat said chamber;
an ultraviolet radiation emitter associated with said chamber; and
a plasma generator configured to act on said front layer.

11. The apparatus according to claim 10, wherein said ultraviolet radiation emitter is configured to emit radiation over a broad band spectrum.

12. The apparatus according to claim 11, wherein the broad band spectrum comprises radiation ranging from ultraviolet to infrared.

13. The apparatus according to claim 10, wherein the plasma generator is configured to produce at least one of: a notch in said front layer between said pads, and a modified surface state of said front layer between said pads.

14. The apparatus according to claim 10, wherein said front layer comprises anti-fusion properties.

15. The apparatus according to claim 14, wherein said anti-fusion properties comprises notches produced in said front layer between said optical microlenses.

16. The apparatus according to claim 14, wherein said anti-fusion properties comprises corrugations formed on said front layer between said pads.

17. A semiconductor device comprising:
a plurality of pads forming optical microlenses on a front layer of said semiconductor device, wherein said front layer comprises anti-fusion properties to prevent the adjacent edges of said pads from fusing together.

18. The device according to claim 17, wherein said anti-fusion properties comprises notches produced in said front layer between said optical microlenses.

19. The device according to claim 17, wherein said anti-fusion properties comprises corrugations formed on said front layer between said pads.

20. The device according to claim 17, wherein said pads comprise a substantially domed shape.
